(19) United States
(12) Patent Application Publication
(10) Pub. No.: US 2026/0113036 A1
(43) Pub. Date: Apr. 23, 2026

(54) CONTACTLESS BUTTON AND BUTTON

(71) Applicant: DARWIN PRECISIONS CORPORATION, Hsinchu County (TW)

(72) Inventors: YAN-MIN LIOU, Hsinchu County (TW); Chih-Hung Liu, Hsinchu County (TW)

(21) Appl. No.: 19/207,335

(22) Filed: May 13, 2025

(30) Foreign Application Priority Data
Oct. 17, 2024 (TW) 113139582

(51) Int. Cl. H03K 17/94; H03K 17/96

(52) U.S. Cl. CPC H03K 17/941; H03K 17/9627

(57) ABSTRACT

A contactless button includes a substrate, a frame, and a sensing module. The frame is arranged on the substrate, and the frame has an opening on a side away from the substrate. The sensing module is adapted for forming a sensing area and has a sensing part that covers the opening. The sensing part has a plurality of layers including a supporting plate, a sheet, and a conductive layer. The supporting plate covers the opening. The sheet completely covers a side of the supporting plate away from the substrate. The conductive layer is located between the sheet and the supporting plate and completely covers the sheet. The conductive layer is electrically connected to the substrate and is adapted for forming the sensing area. A button having the contactless switch function is also provided.

### FIELD OF THE INVENTION

The present invention relates to a contactless button and a button, in particular to the contactless button that can produce a suspending optical image and the contact button that also has a function of the above-mentioned contactless button.

### BACKGROUND OF THE INVENTION

Commonly known contactless buttons, depending on the sensing method, include optically triggered buttons. In order to improve the accuracy of the optical sensor, in addition to providing an opening on a surface of a button for an optical sensor to receive light, there are also designs in which the optical sensor is set on an outer frame of the button. However, with the designs of placing the optical sensor on the outer frame, a sensing range of the optical sensor will be easily affected by a shape of the outer frame. Thence, due to the consideration of the sensing range, the shape of the outer frame is restricted.

### SUMMARY OF THE INVENTION

The present invention provides a contactless button with good sensing accuracy.

The invention also provides a button, which has the functions of both a contact button and the contactless button and has good sensing accuracy.

In order to achieve the above advantages, the present invention provides the contactless button, which includes a substrate, a frame, and a sensing module. The frame is arranged on the substrate, wherein the frame has an opening on one side away from the substrate. The sensing module is adapted for forming a sensing area. The sensing module has a sensing part covering the opening. The sensing part has a plurality of layers, and the layers include a supporting plate, a sheet, and a conductive layer. The sheet completely covers a side surface of the supporting plate away from the substrate. The conductive layer is located between the sheet and the supporting plate and completely covers the sheet, wherein the conductive layer electrically connects to the substrate and is adapted for forming the sensing area.

The present invention further provides a button, which includes a substrate, a frame, a contact switch, and a sensing module. The frame is arranged on a substrate, wherein the frame has an opening on one side away from the substrate. The contact switch is arranged on the substrate and adapted for generating a first control signal. The sensing module is adapted for pushing against the contact switch to generate the first control signal, and is adapted for forming a sensing area for generating a second control signal, wherein the sensing module has a sensing part covering the opening. The sensing part has a plurality of layers, and the layers include a supporting plate, a sheet, and a conductive layer. The sheet completely covers a side surface of the supporting plate away from the substrate. The conductive layer is located between the sheet and the supporting plate and completely covers the sheet, wherein the conductive layer electrically connects the substrate and is adapted for forming the sensing area.

In one embodiment, the supporting plate, the sheet, and the conductive layer are light transmissive.

In one embodiment, the sensing module further includes an optical imaging assembly. The optical imaging assembly is located on one side of the supporting plate close to the substrate. The sensing module is adapted for converting a light beam provided by a light-emitting unit on the substrate into a suspending optical image through the optical imaging assembly, and is adapted for pushing the contact switch through the optical imaging assembly.

In one embodiment, the optical imaging assembly includes a lens array, and the lens array is integrally formed with the supporting plate.

In one embodiment, the sensing module has a plurality of fixing parts. The fixing parts extend from the supporting plate along a direction perpendicular to the surface of the substrate toward the substrate, and are adapted for fixing the optical imaging assembly.

In one embodiment, the sensing module further has an outer flange and a stepped part. The outer flange is formed by extending the supporting plate. The outer flange surrounds the sensing part and is parallel to the substrate. The fixing part is located at a peripheral edge of the outer flange. A thickness of the outer flange is less than a thickness of the sensing part in a direction of the sensing module facing the substrate. And, the stepped part is formed by extending the supporting plate and is located between the sensing part and the outer flange.

In one embodiment, the sheet and the conductive layer completely cover the outer flange and the stepped part.

In one embodiment, the sheet and the conductive layer partially cover the outer flange and the stepped part.

In one embodiment, the sheet is a flexible sheet. The sensing module further includes a connecting part. The connecting part is connected to the outer flange and is composed of the sheet extending from the sensing part and the conductive layer extending from the sensing part. And, the sensing part is electrically connected to the substrate through the connecting part.

Based on the above description, the contactless button of the present invention, by configuring a layer (conductive layer) used to form a sensing area in the sensing part covering an opening to completely cover another layer (supporting plate), can form a homogeneous sensing area in front of the sensing portion, improve sensing accuracy, and does not require additional elements (e.g., frames) for accommodating a sensing element. In addition, by arranging the conductive layer between the sheet and the supporting plate, and also arranging the sheet on the outer surface of the sensing part (the outer surface of the contactless button, which is the side away from the substrate), the conductive layer can be protected through the sheet while sufficient support is provided through the supporting plate. Since the sheet and the conductive layer are supported by the supporting plate, the thickness of the sheet can be thinned so that the conductive layer is as close as possible to the front of the contactless button. This prevents the sensing range from being affected by the thickness of the supporting plate and hence increases the sensing range of the contactless button.

In addition, in some embodiments, during making the supporting plate, the sensing module can form a fixing part through the supporting plate to fix the optical imaging assembly that generates the suspending optical image. In some embodiments, because the flexible sheet and the conductive layer are used to form the connecting part that electrically connects the sensing part to the substrate, not only that no additional connection wires are required, but also can avoid damage to the part extending to the connecting part at the bending part (stepped part) of the sensing module, and thus a degree of freedom in apparent designs of the sensing module is improved.

Furthermore, the button provided by the present invention has the same advantages because the button has the structure of the contactless button mentioned above.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The present invention will become more readily apparent to those ordinarily skilled in the art after reviewing the following detailed description and accompanying drawings, in which:

FIG. 1 is a decomposition schematic diagram of the button according to the first embodiment of the present invention;

FIG. 2 is a three-dimensional schematic diagram of a sensing module according to the embodiment of FIG. 1;

FIG. 3 is a partial cross-sectional schematic diagram of the sensing module according to the embodiment of FIG. 1;

FIG. 4 is the cross-sectional schematic diagram of the button, taken along the section line A-A, according to the embodiment of FIG. 1;

FIG. 5 is a schematic diagram of generating a suspending optical image of the button according to the embodiment of FIG. 1;

FIGS. 6 and 7 are schematic diagrams of an action of the button taken along the section line A-A according to the embodiment of FIG. 1;

FIG. 8 is a decomposition schematic diagram of the contactless button according to an embodiment of the present invention; and

FIG. 9 is a three-dimensional schematic diagram of a sensing module according to the embodiment of FIG. 8.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

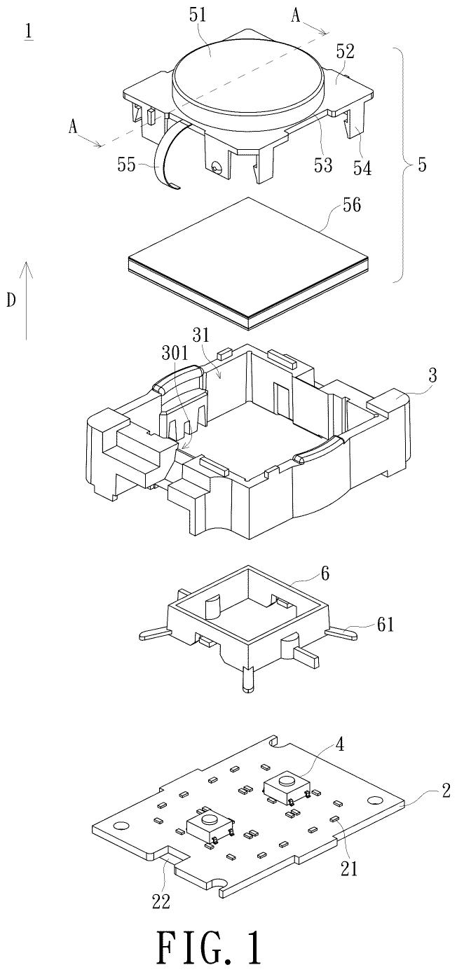

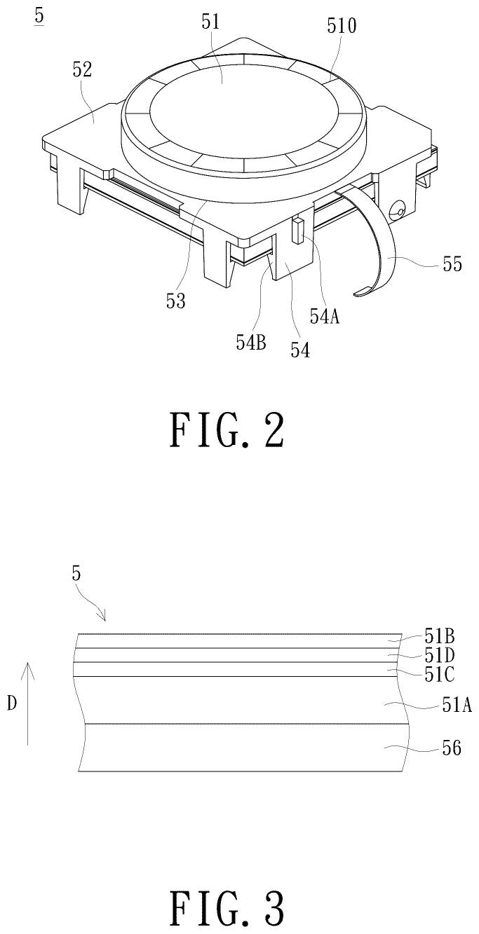

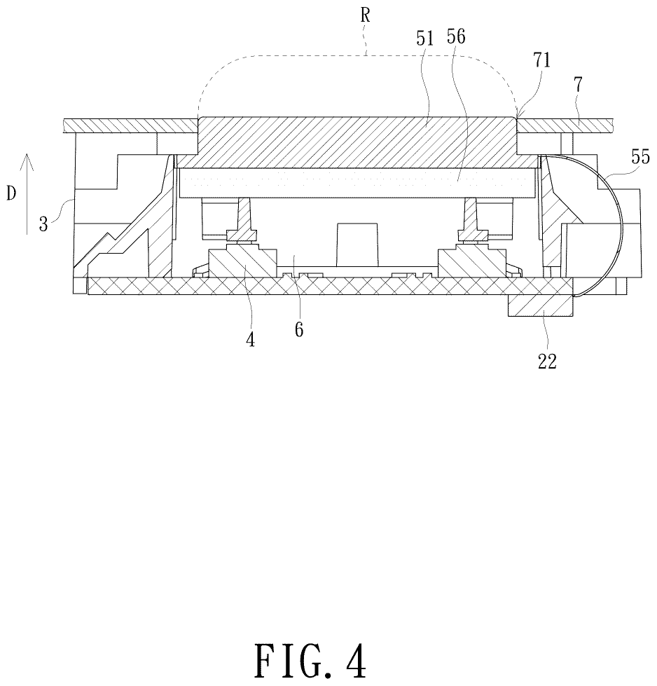

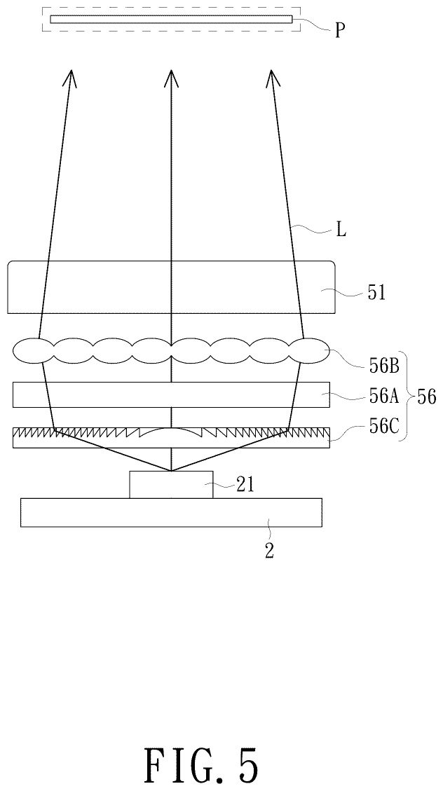

FIG. 1 is a decomposition schematic diagram of a button according to an embodiment of the present invention. FIG. 2 is a three-dimensional schematic diagram of the sensing module according to the embodiment of FIG. 1. FIG. 3 is a partial cross-sectional schematic diagram of the sensing module according to the embodiment of FIG. 1. FIG. 4 is the cross-sectional schematic diagram of the button, taken along the section line A-A, according to the embodiment of FIG. 1. In order to clearly understand the combination relationship between an optical imaging assembly 56 and other components (such as a fixing part 54) of a sensing module 5, FIG. 1 further separates the optical imaging assembly 56 from other components of the sensing module 5. With the following description of the function of generating a signal when pressed, it should be understood that the optical imaging assembly 56 and the other components of the sensing module 5 will operate together when the button 1 is actually activated.

As shown in FIGS. 1 to 4, an embodiment of the present invention provides a button 1, which includes a substrate 2, a frame 3, a contact switch 4, and a sensing module 5. The frame 3 is arranged on the substrate 2, and the frame 3 has an opening 31 on a side away from the substrate 2. The contact switch 4 is arranged on the substrate 2 and adapted for generating a first control signal. The sensing module 5 is adapted for pushing the contact switch 4 to generate the first control signal and adapted for forming a sensing area R for generating a second control signal. The sensing module 5 has a sensing part 51 covering the opening 31. The sensing part 51 has a plurality of layers, and the layers include a supporting plate 51A, a sheet 51B, and a conductive layer 51C (see FIG. 3). The sheet 51B completely covers a side surface of the supporting plate 51A away from the substrate 2. The conductive layer 51C is located between the sheet 51B and the supporting plate 51A and completely covers the sheet 51B. The conductive layer 51C is electrically connected to the substrate 2 and is adapted for forming the sensing area R (see FIG. 4).

According to the present invention, there is no restriction on the installation object of the button 1, and the button 1 can be installed to, such as but not limited to, an elevator. As shown in FIG. 4, during installation, the button 1 is, for example, mounted on a device that uses the button 1, such as a decorative plate 7 of the elevator, and only the sensing module 5 is exposed. In the embodiment shown in FIG. 4, in a direction D of the substrate 2 toward the sensing module 5, the sensing module 5 is, for example, located in the foremost front of the entire button 1, and a surface of the sensing module 5 is aligned with a surface of the decorative plate 7, but is not limited thereto.

According to the present invention, there is no restriction on the type of the substrate 2. The substrate 2 is, for example, a printed circuit board (PCB). The shape and size of the substrate 2, for example, correspond to an opening 31 size of the frame 3 and are slightly larger than the frame 3, or can be equal to the opening 31 size of the frame 3, but are not limited thereto.

In the present embodiment, for example, the substrate 2 is arranged with a plurality of light-emitting units 21 on a side facing the sensing module 5, and an interface 22 adapted for electrical connection with the sensing module 5 is arranged on the opposite side. The interface 22 is, for example, a flexible flat cable (FFC) connector, but is not limited thereto. In another embodiment (not shown in the figures), the interface 22 can be arranged on a same side as the plurality of light-emitting units 21. The light-emitting units 21 are arranged on the substrate 2, for example, arranged next to the contact switch 4. When the substrate 2 is assembled with the frame 3, the light-emitting unit 21 is, for example, surrounded by the frame 3. The interface 22 is, for example, located at the edge of the substrate 2, but is not limited thereto.

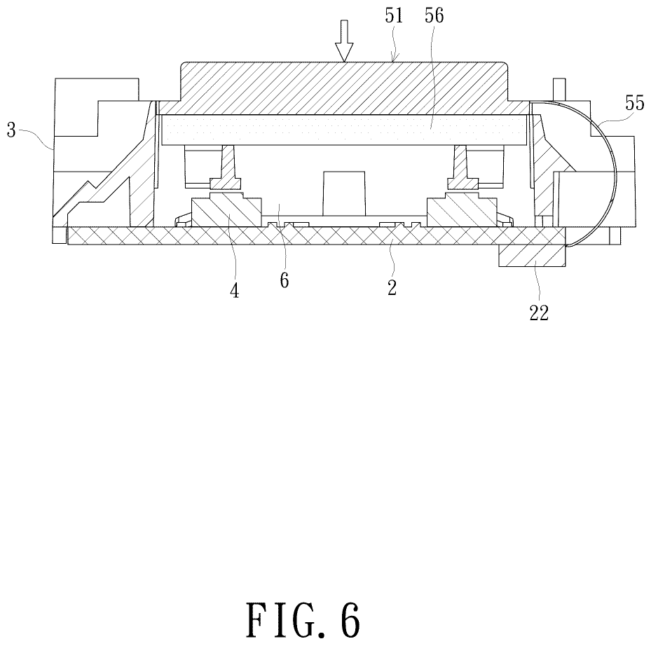

The light-emitting unit 21 is adapted to project a light beam L toward the sensing module 5 and form a suspending optical image P in front of the button 1 under the action of the sensing module 5 (see FIG. 5, described in detail later). The light-emitting unit 21 is, for example, a light-emitting diode (LED), but is not limited thereto. A wavelength of the light beam L generated by the light-emitting unit 21 is not restricted, and the light beam L can be, for example, visible light.

According to the present embodiment, the frame 3 is, for example, a rectangular frame. A shape of the frame 3 corresponds to, for example, a shape of the substrate 2 or a shape of the sensing module 5, but is not limited thereto. The size of the internal space surrounded by the frame 3 can be set according to demands, for example, the size is large enough to accommodate components such as the contact switch 4, the sensing module 5, the middle frame 6, and the light-emitting units 21. The size of the opening 31 of the frame 3, for example, corresponds to the size of the sensing module 5 and is larger than the size of the opening 71 on the decorative plate 7, but is not limited thereto. There is no restriction on the material of the frame 3, and the material can be selected according to demands.

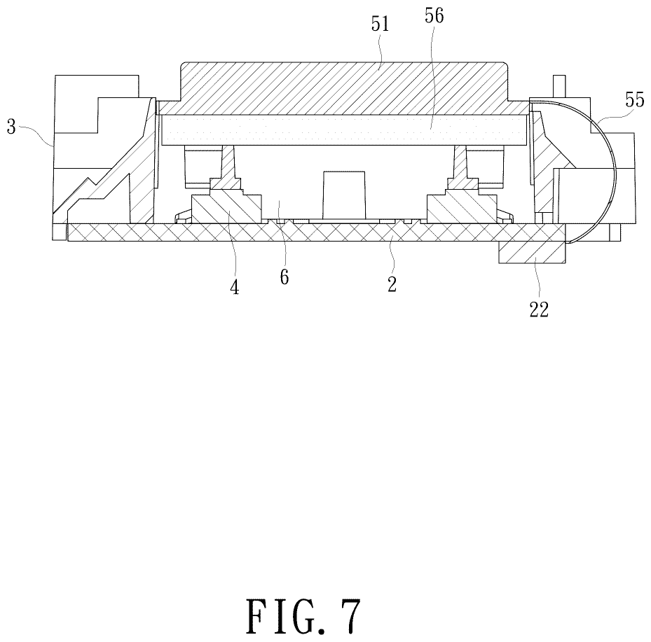

As shown in FIG. 1, in the present embodiment, the button 1 includes, for example, a middle frame 6. The middle frame 6 is adapted to be pushed by the sensing module 5 to contact the contact switch 4 when the button 1 is pressed (see FIGS. 6 and 7). The middle frame 6 is arranged between the substrate 2 and the sensing module 5. The shape of the middle frame 6 is not restricted, for example, the shape of the middle frame 6 corresponds to the shape of the frame 3. A plurality of elastic arms 61 is, for example, arranged on a peripheral edge of the middle frame 6. For example, the elastic arm 61 extends obliquely in a direction from the middle frame 6 toward the substrate 2, so that when the middle frame 6 is not acted upon by an external force, there is a gap between the middle frame 6 and the contact switch 4 (see FIG. 6, the gap between the contact switch 4 and a cross-sectional view of the inverted T-shaped middle frame 6 above the contact switch 4, wherein some lines are deleted for convenience of representation of the gap).

In the present embodiment, the contact switch 4 is, for example, a push-button switch (or tactile switch), which is adapted for generating the first control signal when contacted by the sensing module 5 or the middle frame 6, but a contact object is not limited thereto.

In another embodiment not shown in the figures, the contact switch 4 is, for example, a limit switch and includes, for example, a cap (not shown in the figures) for contacting the sensing module 5. The cap is adapted to move and generate the first control signal when pushed by the sensing module 5 or the middle frame 6. In some embodiments where the contact switch 4 is a limit switch, when the contact switch 4 is assembled with the substrate 2, the cap can be pushed away from the substrate 2 by an elastic member (not shown in the figures) in the contact switch 4. Therefore, in some embodiments of this type, the contact switch 4 can directly contact the sensing module 5 or the middle frame 6 when the button 1 is not acted upon by an external force. The first control signal is generated as long as the contact switch 4 moves to the bottom end of its movable stroke when the cap approaches the substrate 2. It should be understood that in other embodiments, when the button 1 is not acted upon by an external force, the limit switch serving as the contact switch 4 does not contact the sensing module 5 or the middle frame 6 until the button 1 is acted upon by the external force.

The difference between the first control signal generated by the contact switch 4 and the second control signal generated by the conductive layer 51C is the sources of the generated signals. However, for a device equipped with the button 1, the first control signal and the second control signal can be instructions for executing a same function, but are not limited thereto.

FIGS. 6 and 7 are schematic diagrams of an action of the button taken along the section line A-A according to the embodiment of FIG. 1. As shown in FIGS. 6 and 7, the middle frame 6 is adapted for changing the shape of the elastic arm 61 by being pushed by a user (specifically, by the optical imaging assembly 56 at the bottom of the sensing module 5), and then moves toward the substrate 2 and contacts or pushes the contact switch 4 on the substrate 2.

As shown in FIG. 1 and FIG. 4, in the present embodiment, the sensing module 5 is adapted to receive induction to generate a second control signal, and is adapted to cooperate with the contact switch 4 to generate the first control signal. For example, the sensing module 5 roughly corresponds to the shape of the opening 31 and covers the entire opening 31, but is not limited thereto. In the present embodiment, the sensing module 5 includes, for example, a sensing part 51 adapted for forming a sensing area R and the optical imaging assembly 56.

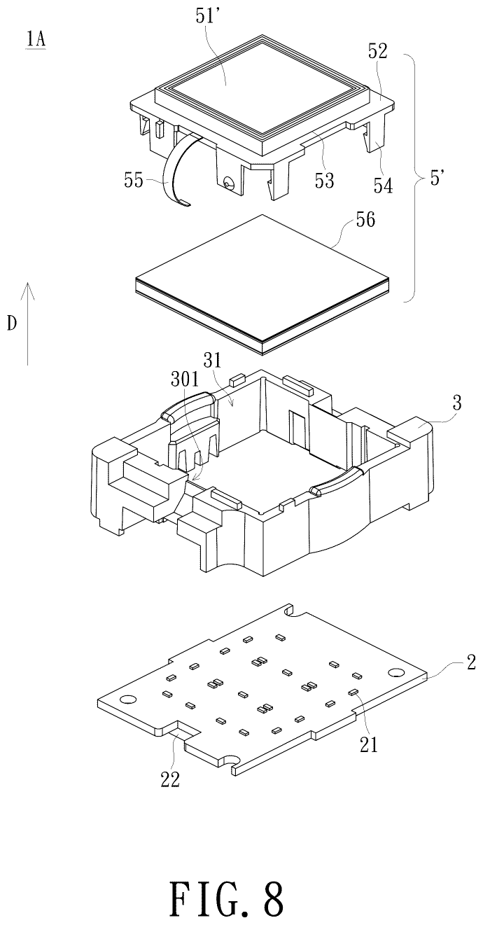

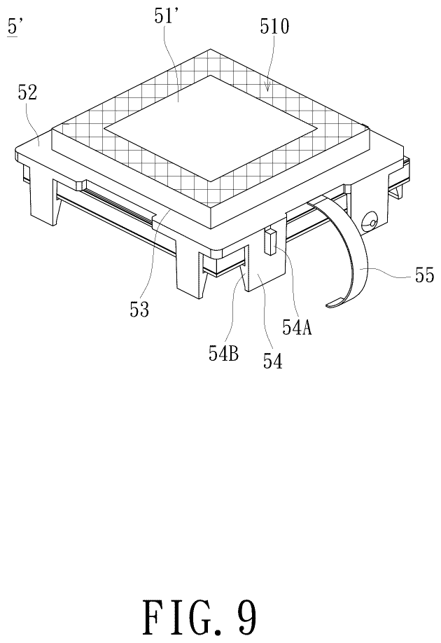

In the present embodiment, the sensing module 5 has the sensing part 51. The sensing part 51 is adapted for forming the sensing area R of the sensing module 5. In the present embodiment, the sensing part 51 is the part of the sensing module 5 that is exposed on the decorative plate 7 (see FIG. 4) and can sense the proximity of a finger and can be in contact with the finger, but is not limited thereto. The sensing part 51 corresponds to the shape of the opening 71 on the decorative plate 7 and is, for example, cylindrical, but can be set according to demands (see the embodiments of FIGS. 8 and 9 described below for details). Referring to FIGS. 2 and 3, the sensing part 51 is composed of a plurality of layers. Since the layers not only constitute the sensing part 51 in the present embodiment but can also constitute other parts of the sensing module 5, the layers will be described hereinafter.

In the present embodiment, the layers include, for example, the supporting plate 51A, the sheet 51B, and the conductive layer 51C.

As shown in FIGS. 1 to 4, in the present embodiment, the supporting plate 51A is, for example, located below the conductive layer 51C and the sheet 51B. The supporting plate 51A is adapted for providing support when the sensing module 5 is pressed, which improves the durability of the conductive layer 51C and the sheet 51B. Since the supporting plate 51A is located below the sheet 51B and the conductive layer 51C, a thickness of the supporting plate 51A will not affect a range of the sensing area R formed through the conductive layer 51C. In the case that support can be provided, the thickness or shape of the supporting plate 51A can be designed according to functions and other requirements. A material of the supporting plate 51A is, for example, acrylic resin, and is light transmissive, but is not limited thereto. The supporting plate 51A is, for example, formed by placing the assembly of the sheet 51B and the conductive layer 51C into a mold (not shown in the figures) and then making plastic injection, but is not limited thereto.

As shown in FIG. 3, the sheet 51B is, for example, a layer covering a side of the supporting plate 51A. The sheet 51B is, for example, a flexible sheet 51B, and is, for example, an electronic flexible board such as a flexible printed circuit board (Flexible PCB) or a flexible flat cable (FFC), and is, for example, a light transmissive component, but is not limited thereto.

The conductive layer 51C is adapted for forming the sensing area R. The conductive layer 51C in the sensing part 51 is, for example, a layer that completely covers a side surface of the sheet 51B. The conductive layer 51C can be a light transmissive layer composed of metal wires that are difficult to see with the naked eye, and can form a transparent conductive film together with the sheet 51B. The material of the conductive layer 51C includes, for example, one or a combination of indium tin oxide (ITO), graphene, aluminum-doped zinc oxide (Al-doped ZnO), carbon nanotube (CNT), or other conductive polymer materials. In some embodiments, in addition to the conductive layer 51C, other conductive wires (not shown in the figures) can also be arranged on the sheet 51B.

As shown in FIGS. 3 and 4, in the present embodiment, the conductive layer 51C and the sheet 51B that constitute the sensing part 51 cover a side of the supporting plate 51A away from the substrate 2, and the sensing part 51 covers the opening 31 of the frame 3. Therefore, through the range of the sensing area R formed by the sensing part 51, a complete and uniform sensing range is formed in a space in front of the sensing module 5 (top in FIG. 4). In other words, in the space exposed in front of the decorative plate 7, the button 1 will not have different sensing distances due to different locations.

As shown in FIGS. 2 and 3, in the present embodiment, the layers of the sensing part 51 further include, for example, a pattern layer 51D. The pattern layer 51D is, for example, located between the sheet 51B and the conductive layer 51C, but is not limited thereto. The pattern layer 51D is, for example, a layer formed through light transmissive ink or light opaque ink, and is adapted for forming a pattern 510 presented on the sensing part 51. The pattern 510 is, for example, arranged according to the shape of the sensing part 51 but is not limited thereto. In an embodiment not shown in the figures, for example, a light transmissive opening can be arranged on the pattern layer 51D.

As shown in FIGS. 1 and 2, in the present embodiment, the sensing module 5 further includes, for example, an outer flange 52. The outer flange 52 is adapted for adjusting an outer contour of the sensing module 5 so that the sensing part 51 is not limited to a contour shape of the opening 31. As shown in FIG. 2, the outer flange 52 is formed by extending the supporting plate 51A. The outer flange 52 surrounds the sensing part 51 and extends parallel to the substrate 2 (a surface of the sensing part 51), and is located on a side of the sensing part 51 close to the substrate 2 on the extension line of the direction D, so that the sensing part 51 appears to be a convex bump protruding toward a side away from the substrate 2. The outer flange 52 is adapted to cover the opening 31 of the frame 3 together with the sensing part 51, and during assembly, is covered by the decorative plate 7 and does not expose the opening 71 of the decorative plate 7. In the direction of the sensing module 5 facing toward the substrate 2 (a direction opposite to the direction D in FIG. 1), a thickness of the outer flange 52 is, for example, smaller than a thickness of the sensing part 51.

In the present embodiment, because the thickness of the outer flange 52 and the thickness of the sensing part 51 are different, the sensing module 5 further forms a stepped part 53 between the outer flange 52 and the sensing part 51, but is not limited thereto. A height of the stepped part 53 can correspond to a thickness of the decorative plate 7, so that the surface of the sensing part 51 is aligned with the surface of the decorative plate 7, but is not limited thereto. The stepped part 53 is, for example, formed by extending the supporting plate 51A, and is located between the sensing part 51 and the outer flange 52.

It should be understood that in the present embodiment, the outer flange 52 and the stepped part 53 are only used to adjust whether the contours and surfaces of the sensing part 51, the opening 31 on the frame 3, and the opening 71 on the decorative plate 7 are aligned. Therefore, in the embodiment not shown in the figures, the sensing module 5 may not have the outer flange 52 and the stepped part 53, or may only have the outer flange 52. In addition, although the outer flange 52 and the stepped part 53 are mainly extended by the supporting plate 51A, the relationship between the outer flange 52 and the stepped part 53 with other layers (such as the sheet 51B and the conductive layer 51C) is not particularly limited. In other words, in some embodiments of the present invention, the sheet 51B and the conductive layer 51C can completely cover the outer flange 52 and the stepped part 53 and thus change the size and shape of the sensing range R. However, in other embodiments, the conductive layer 51C and the sheet 51B can also partially cover the outer flange 52 and the stepped part 53 (see a connecting part 5 described below for details), and thus make the sensing range R mainly only affected by the sensing part 51.

As shown in FIG. 2, in the present embodiment, the sensing module 5 has a plurality of fixing parts 54. The fixing parts 54 are adapted for fixing the optical imaging assembly 56 (described below) in the sensing module 5. The fixing parts 54 are, for example, members extending from the supporting plate 51A along a direction perpendicular to the surface of the substrate 2 (the opposite direction to the direction D in FIG. 1) toward the substrate 2. In the present embodiment, the fixing parts 54 extend from the outer flange 52 toward the substrate 2, for example, but are not limited thereto. During manufacturing, the fixing parts 54 are, for example, integrally formed with the sensing part 51 and the outer flange 52, but are not limited thereto.

As shown in FIG. 2, in the present embodiment, the fixing part 54 is, for example, arranged with a guide rail 54A extending along the direction D, but is not limited thereto. The guide rail 54A is adapted for sliding on an inner wall surface of the frame 3 and guiding the sensing module 5 to slide relative to the inner wall surface of the frame 3. In some embodiments, since the guide rail 54A is a bump that slides against the frame 3, the wall surface of the frame 3 can be pushed against a top or a bottom surface of the guide rail 54A (please refer to a direction in FIG. 2) to prevent the sensing module 5 from leaving the frame 3 along the direction D, but the detailed design is not limited thereto.

As shown in FIG. 2, in the present embodiment, the fixing part 54 has, for example, a claw 54B at one end away from the sensing part 51. The claw 54B is, for example, composed of a block protruding toward the center of the supporting plate 51A. During assembly, the claw 54B is adapted for hooking the optical imaging assembly 56 that will be described later on. However, the detailed design of how the fixing part 54 fixes the optical imaging assembly 56 is not limited thereto.

As shown in FIG. 1, FIG. 3 and FIG. 4, in the present embodiment, the sensing module 5 has, for example, a connecting part 55. The sensing part 51 can be electrically connected to the interface 22 of the substrate 2 through the connecting part 55. The connecting part 55 is, for example, composed of the sheet 51B extending from the sensing part 51 and the conductive layer 51C extending from the sensing part 51, but is not limited thereto. Specifically, in the present embodiment, the connecting part 55 extends from the surface of the sensing part 51 through the stepped part 53 and the surface of the outer flange 52 to an outside of the outer flange 52. During assembly, the connecting part 55 passes through the notch 301 located on a side of the opening 31 of the frame 3 and is connected to the interface 22 of the substrate 2 across the frame 3, but is not limited thereto.

Through the above structure, the connecting part 55 is directly formed by the sheet 51B extending from the sensing part 51, and therefore, the conductive layer 51C and the sensing module 5 can be electrically connected to the substrate 2 through the conductive layer 51C on the connecting part 55 without a need for additional conductive wires. Since the connecting part 55 passes through the space surrounded by the frame 3, there is a larger space for gradual bending, thereby preventing the connecting part 55 from breaking due to excessive bending. It should be understood that in some embodiments, the sheet 51B constituting the connecting part 55 may also have thick and light-impermeable wires that are electrically connected to the conductive layer 51C of the sensing part 51, so that the connecting part 55 does not necessarily need to have the conductive layer 51C.

There is no restriction on a connection method between the connecting part 55 and the substrate 2. In the embodiment not shown in the figures where the supporting plate 51A is manufactured by an injection molding method, the extending direction of the sheet 51B that subsequently constitutes the connecting part 55 can be adjusted before the supporting plate 51A is manufactured. Therefore, in the embodiment not shown in the figures, the connecting part 55 can be a member that passes through the outer flange 52 on a same axis as the direction D, and the connecting part 55 is connected to the substrate 2 in the space surrounded by the middle frame 6 or the frame 3, and does not necessarily need to be connected to the substrate 2 from an outside of the frame 3.

As shown in FIGS. 1 to 4, in the present embodiment, the sensing module 5 further includes the optical imaging assembly 56. Through the fixing part 54, the optical imaging assembly 56 is, for example, arranged on the side of the sensing part 51 close to the substrate 2. The supporting plate 51A, the sheet 51B, and the conductive layer 51C are all light transmissive parts, so that the light beam L generated by the light-emitting unit 21 can pass through the supporting plate 51A, the sheet 51B, and the conductive layer 51C after passing through the optical imaging assembly 56 and can form a suspending optical image P (see FIG. 4) in front of the button 1. In other words, in the present embodiment, the sensing module 5 is not only adapted for receiving induction to generate a second control signal and for matching the contact switch 4 to generate a first control signal, but is also adapted for forming a suspending optical image P.

A shape of the optical imaging assembly 56 corresponds, for example, to the shape of the sensing part 51, but is not limited thereto. The optical imaging assembly 56 includes, for example, a plurality of plate-shaped elements, such as an imaging unit 56A, a lens array 56B, and a light path conversion unit 56C.

The imaging unit 56A is opposite to the lens array 56B and faces the substrate 2. The imaging unit 56A is, for example, a film with a preset pattern, a photomask, or a layer film sheet, but is not limited thereto. The preset pattern on the imaging unit 56A corresponds to the suspending optical image P to be presented after the light beam L passes through the optical imaging assembly 56. A location of the suspending optical image P, for example, corresponds to a location of the sensing part 51. An image content of the suspending optical image P is not restricted; for example, the suspending optical image P corresponds to a pattern required by the device installed on the button 1, such as a number representing an elevator floor or a pattern indicating the intention of an operation command input through the button 1.

The lens array 56B is, for example, a lenticular lens array 56B, which is adapted for allowing the light beam L passing therethrough to form a three-dimensional image. In other embodiments not shown in the figures, the lens array 56B can also be a single-sided convex lens array 56B, which can be configured according to requirements. A material of the lens array 56B is not restricted, such as glass or transparent acrylic resin. In some embodiments, the lens array 56B and the supporting plate 51A can be manufactured simultaneously and integrally formed, but are not limited thereto.

The light path conversion unit 56C is arranged on a side of the imaging unit 56A, and the imaging unit 56A is located between the lens array 56B and the light path conversion unit 56C. The light path conversion unit 56C is adapted for diffusing the light beam L and/or converting the light beam L into a parallel light beam to improve the brightness of the suspending optical image P. The light path conversion unit 56C is, for example, a Fresnel lens. The material of the light path conversion unit 56C can refer to the aforementioned description of the lens array 56B, but is not particularly limited thereto.

It should be understood from FIG. 6, FIG. 7, and the above description that in the present embodiment, the optical imaging assembly 56 pushes against the middle frame 6 to contact the contact switch 4. However, in the embodiment not shown in the figures, the sensing module 5 may not have the optical imaging assembly 56. Or, the contact position between the middle frame 6 and the sensing module 5 is changed, for example, the fixing part 54 does not indirectly trigger the contact switch 4 through the optical imaging assembly 56.

Through the above method, in addition to directly placing the sheet 51B on the surface of the sensing module 5 so that the conductive layer 51C is as close as possible to a user's finger while being covered and protected by the sheet 51B, the thickness or the material of the supporting plate 51A can also be adjusted so that the sensing module 5 can provide sufficient support when used as a component pressed by the user's finger. During manufacturing the supporting plate 51A, the fixing component (fixing part 54) for fixing the optical imaging assembly 56 can also be made without a need for additional fixing components. The fixing part 54 can also avoid using glue to assemble the optical imaging assembly 56, which affects the optical performance of the optical imaging assembly 56. At the same time, through such technology, a conductive structure composed of the sheet 51B and the conductive layer 51C can avoid the problem of circuit breakage at the stepped part 53 due to an excessive bending, and can make the sheet 51B and the conductive layer 51C as thin as possible.

FIG. 8 is a schematic diagram of a contactless button according to an embodiment of the present invention, and FIG. 9 is a three-dimensional schematic diagram of a sensing module according to the embodiment of FIG. 8. As shown in FIGS. 1, 8, and 9, the present invention provides a contactless button 1A. The difference from the aforementioned button 1 is that except for a shape of a sensing part 51′ of a sensing module 5′ (changed to a rectangular shape), the other difference is that the contactless button 1A does not have the contact switch 4 and the middle frame 6, so for the design of the contactless button 1A, please refer to the description of the aforementioned button 1.

Based on the above description, the contactless button of the present invention has a structure in which the conductive layer used to form the sensing area in the sensing part covering the opening is configured to completely cover the supporting plate of the sensing part. Therefore, the uniform sensing range can be formed in front of the contactless button, improving sensing accuracy, and does not require additional arrangements (such as outer frames) to accommodate the sensing elements. In addition, by arranging the conductive layer between the sheet and the supporting plate, and also arranging the sheet on the outer surface of the sensing part (the outer surface of the contactless button, which is the side away from the substrate), the conductive layer can be protected through the sheet while sufficient support is provided through the supporting plate. Since the sheet and the conductive layer are supported by the supporting plate, the thickness of the sheet can be thinned so that the conductive layer is as close as possible to the front of the contactless button. This prevents the sensing range from being affected by the thickness of the supporting plate and hence increases the sensing range of the contactless button.

In addition, in some embodiments, the sensing module can integrate the optical imaging assembly that generates the suspending optical image through the fixing part formed by the supporting plate. In some embodiments, because the flexible sheet and the conductive layer are used to form the connecting part that electrically connects the sensing part to the substrate, not only that no additional connection wires are required, but also can avoid damage to the part extending to the connecting part at the bending part (stepped part) of the sensing module, and thus a degree of freedom in apparent designs of the sensing module is improved.

Furthermore, the button provided by the present invention has the same advantages because the button has the structure of the contactless button mentioned above.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A contactless button, comprising:
a substrate;
a frame, arranged on the substrate, wherein the frame has an opening on one side away from the substrate; and
a sensing module, adapted for forming a sensing area, wherein the sensing module has a sensing part covering the opening, the sensing part has a plurality of layers, and the layers comprise:
a supporting plate;
a sheet, covering a side surface of the supporting plate away from the substrate; and
a conductive layer, located between the sheet and the supporting plate and completely covering the sheet, wherein the conductive layer electrically connects the substrate and is adapted for forming the sensing area.

2. A button, comprising:
a substrate;
a frame, arranged on the substrate, wherein the frame has an opening on one side away from the substrate;
a contact switch, arranged on the substrate and adapted for generating a first control signal; and
a sensing module, adapted for pushing against the contact switch to generate the first control signal and adapted for forming a sensing area for generating a second control signal, wherein the sensing module has a sensing part covering the opening, the sensing part has a plurality of layers, and the layers comprise:
a supporting plate;
a sheet, completely covering a side surface of the supporting plate away from the substrate; and
a conductive layer, located between the sheet and the supporting plate and completely covering the sheet, wherein the conductive layer electrically connects the substrate and is adapted for forming the sensing area.

3. The button according to claim 2, wherein the supporting plate, the sheet, and the conductive layer are light transmissive.

4. The button according to claim 3, wherein the sensing module further comprises an optical imaging assembly, the optical imaging assembly is located on one side of the supporting plate close to the substrate, and the sensing module is adapted for converting a light beam provided by a light-emitting unit on the substrate into a suspending optical image through the optical imaging assembly and is adapted for pushing the contact switch through the optical imaging assembly.

5. The button according to claim 4, wherein the optical imaging assembly comprises a lens array, and the lens array is integrally formed with the supporting plate.

6. The button according to claim 4, wherein the sensing module has a plurality of fixing parts, and the fixing parts extend from the supporting plate along a direction perpendicular to the surface of the substrate toward the substrate, and are adapted for fixing the optical imaging assembly.

7. The button according to claim 6, wherein the sensing module further has an outer flange and a stepped part, the outer flange is formed by extending the supporting plate, the outer flange surrounds the sensing part and is parallel to the substrate, the fixing part is located at a peripheral edge of the outer flange, a thickness of the outer flange is less than a thickness of the sensing part in a direction of the sensing module facing the substrate, and the stepped part is formed by extending the supporting plate and is located between the sensing part and the outer flange.

8. The button according to claim 7, wherein the sheet and the conductive layer completely cover the outer flange and the stepped part.

9. The button according to claim 7, wherein the sheet and the conductive layer partially cover the outer flange and the stepped part.

10. The button according to claim 7, wherein the sheet is a flexible sheet, the sensing module further comprises a connecting part, the connecting part is connected to the outer flange and is composed of the sheet extending from the sensing part and the conductive layer extending from the sensing part, and the sensing part is electrically connected to the substrate through the connecting part.
